(19) United States
(12) Patent Application Publication
(10) Pub. No.: US 2026/0334233 A1
(43) Pub. Date: Oct. 22, 2026

(54) SEMICONDUCTOR DEVICE AND METHOD OF MANUFACTURING THE SAME

(71) Applicant: SK hynix Inc., Icheon-si (KR)

(72) Inventor: Heon Yong CHANG, Icheon-si (KR)

(21) Appl. No.: 19/303,008

(22) Filed: Aug. 18, 2025

(30) Foreign Application Priority Data
Apr. 22, 2025 (KR) 10-2025-0052245

(51) Int. Cl. H10W 42/00; H10W 46/00

(52) U.S. Cl. CPC H10W 42/121; H10W 46/00; H10W 46/301; H10W 46/503

(57) ABSTRACT

A substrate includes a chip region and a scribe lane region located outside the chip region; a plurality of key trench segments disposed in the scribe lane region and arranged along a first direction parallel to a boundary between the chip region and the scribe lane region; and at least one buffer trench disposed in the scribe lane region, located between the chip region and the plurality of key trench segments, and formed along the first direction.

### CROSS-REFERENCES TO RELATED APPLICATION

The present application claims priority under 35 U.S.C. 119(a) to Korean patent application number 10-2025-0052245 filed on Apr. 22, 2025, which is incorporated herein by reference in its entirety.

### BACKGROUND

Embodiments of the present disclosure relate to a semiconductor device and method of manufacturing the same.

Due to characteristics such as miniaturization, multifunctionality, and/or low manufacturing cost, semiconductor devices are emerging as important elements in the electronics industry. As the electronics industry advances, semiconductor devices are increasingly required to achieve higher integration.

To meet the demand for high integration, a semiconductor device may include a redistribution layer (RDL) pattern. The redistribution layer pattern may be electrically connected to a chip pad and may extend from an area where the chip pad is disposed to another area. That is, for example, the RDL pattern serves to "redistribute" the electrical connections from the chip's core to a reconfigured layout optimized for packaging. The RDL enables the densely spaced input/output (I/O) pads or bumps of the original chip to be redistributed over a broader area with increased spacing. The redistribution facilitates more reliable and accessible electrical connections to a package substrate or to other chips in a multi-chip module.

### SUMMARY

The scope of embodiments of the present disclosure are not limited to the features described herein. Additional features and advantages will become apparent to those of ordinary skill in the art from the following description.

Embodiments of the present disclosure may provide a semiconductor device capable of preventing degradation of device characteristics caused by process defects, e.g., from mechanical sawing induced crack propagating in a direction perpendicular to the sawing direction during wafer dicing that can potentially damage sensitive edge structures of the chips.

Embodiment of the present disclosure may provide introduce buffer trenches positioned between a key trench and a guard ring. Each buffer trench may be filled with a trench buffer layer and may act as a physical barrier and an energy-absorbing structure, thereby interrupting crack propagation paths during dicing and shielding the chip from damage.

Embodiments of the present disclosure may provide a semiconductor device comprising: a substrate including a chip region and a scribe lane region located outside the chip region; a plurality of key trench segments disposed in the scribe lane region along a first direction parallel to a boundary between the chip region and the scribe lane region; and at least one buffer trench disposed in the scribe lane region between the chip region and the plurality of key trench segments, the at least one buffer trench being arranged along the first direction.

A semiconductor device may be provided that comprises: a substrate including a chip region and a scribe lane region located outside the chip region; a plurality of key trench segments disposed in the scribe lane region; and at least one buffer trench disposed in the scribe lane region between the chip region and the plurality of key trench segments, wherein a length of the at least one buffer trench in the first direction is greater than a length of each of the plurality of key trench segments in the first direction.

Embodiments of the present disclosure may provide a method of manufacturing a semiconductor device, comprising: providing a substrate including a scribe lane region and a chip region; forming a guard ring in the chip region; forming a key trench in the scribe lane region; and forming a first buffer trench in the scribe lane region between the guard ring and the key trench, wherein the first buffer trench is configured to reduce mechanical stress transmission or mitigate crack propagation during wafer singulation.

According to embodiments of the present disclosure, degradation of device characteristics in a semiconductor device due to process defects may be prevented.

The effects of embodiments of the present disclosure are not limited to those mentioned above, and other effects not explicitly mentioned may be clearly understood by those skilled in the art from the description of the claims.

### BRIEF DESCRIPTION OF THE DRAWINGS

The present disclosure will be more fully understood from the detailed description and accompanying drawings provided below, which are provided solely for explanation purposes and do not limit the scope of the present disclosure.

FIG. 1 is a diagram illustrating a wafer in which semiconductor devices according to embodiments of the present disclosure are integrated.

FIG. 2 is a plan view illustrating an enlarged view of an area A of FIG. 1, showing an embodiment of a semiconductor device.

FIG. 3 is a diagram illustrating examples of cross-sectional structures taken along lines I-I′ and II-II′ of FIG. 2.

FIGS. 4-8 are cross-sectional views or enlarged plan views illustrating methods of manufacturing a semiconductor device according to the embodiment disclosed in FIG. 2.

FIGS. 9 and 10 are plan views illustrating other embodiments of a semiconductor device disclosed in FIG. 1, showing an enlarged view of area A of FIG. 1.

FIG. 11 is a diagram illustrating examples of cross-sectional structures taken along lines I-I′ and II-II′ of FIG. 10.

FIG. 12 is a plan view illustrating another embodiment of a semiconductor device disclosed in FIG. 1, showing an enlarged view of area A of FIG. 1.

FIG. 13 is a plan view illustrating another embodiment of a semiconductor device disclosed in FIG. 1, showing an enlarged view of area A of FIG. 1.

FIG. 14 is a diagram illustrating examples of cross-sectional structures taken along lines I-I′ and II-II′ of FIG. 13.

FIGS. 15-20 are cross-sectional views or plan views enlarged from a region B, illustrating examples of a method of manufacturing a semiconductor device according to the embodiment disclosed in FIG. 13.

FIG. 21 is a plan view illustrating another embodiment of a semiconductor device disclosed in FIG. 1, showing an enlarged view of area A of FIG. 1.

### DETAILED DESCRIPTION

Hereinafter, embodiments of the disclosure are described in detail with reference to the accompanying drawings. In assigning reference numerals to components in each drawing, identical components may be assigned the same reference numerals even when shown in different drawings. If details of known art or functions are deemed to obscure the subject matter of the disclosure, such details may be omitted. As used herein, terms such as “includes,” “has,” or “is composed of” in relation to a component may permit the inclusion of additional components unless terms like “only” are explicitly used. Additionally, unless the context clearly indicates otherwise, expressions in the singular, such as “a,” “an,” and “the” are intended to include their plural forms.

Such denotations as “first," "second," "A," "B," "(a)," and "(b)" may be used to describe components of the disclosure. These denotations are intended merely to distinguish one component from another, and are not intended to limit the nature, order, sequence, or number of the components.

Regarding the description of positional relationships between components, when two or more components are described as being "connected," "coupled," or "linked," it should be understood that they may be directly "connected," "coupled," or "linked," or may have an intervening component. Here, the intervening component may be included in one or more of the two or more components that are “connected,” “coupled,” or “linked” to each other.

When terms such as “after,” “next,” “subsequent to” or “before,” are used to describe the temporal or sequential relationships between components, operation methods, or fabrication methods, they may also encompass a non-continuous case unless terms like “immediately” or “directly” are explicitly used.

When a component is associated with a value or its corresponding information (e.g., level), such value or information may be interpreted to include tolerances arising due to various factors (e.g., process variations, internal or external impacts, or noise), even without explicit separate descriptions.

Hereinafter, various embodiments of the disclosure are described in detail with reference to the accompanying drawings.

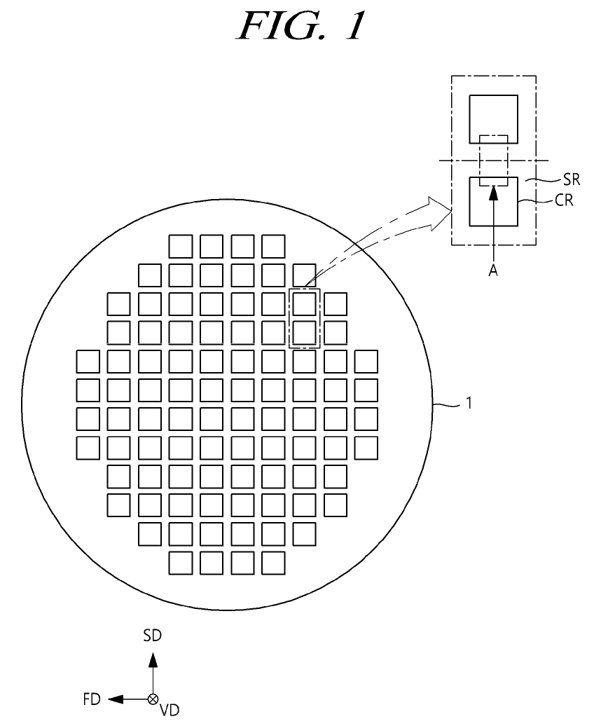

FIG. 1 is a view illustrating a wafer 1 in which semiconductor devices according to embodiments of the present disclosure are integrated.

Referring to FIG. 1, the wafer 1 may include a chip region CR and a scribe lane region SR.

The chip regions CR may be regions that become individual semiconductor chips after the wafer 1 is diced. Integrated circuits for functioning as individual semiconductor chips may be present in each chip region CR.

A direction parallel to a top surface of a substrate may be defined as a first direction FD. A direction intersecting the first direction FD may be defined as a second direction SD. The first direction FD and the second direction SD may be substantially perpendicular to each other. A direction that vertically protrudes from the upper surface of the substrate may be defined as a third direction VD.

The scribe lane region SR may extend along the first direction FD and the second direction SD, intersecting each other so as to surround the side surfaces of each chip region CR. The scribe lane region SR may be continuous with the chip region CR. The scribe lane region SR may be located outside the chip region CR. The wafer 1 may be diced along cutting lines within the scribe lane region SR by a laser, a blade, or the like during a dicing process.

Referring again to FIG. 1, a partial region of the wafer 1 may include a partial region of a first semiconductor device and a partial region of a second semiconductor device adjacent thereto. A region in which the partial regions of the first and second semiconductor devices are adjacent may be defined as an A region.

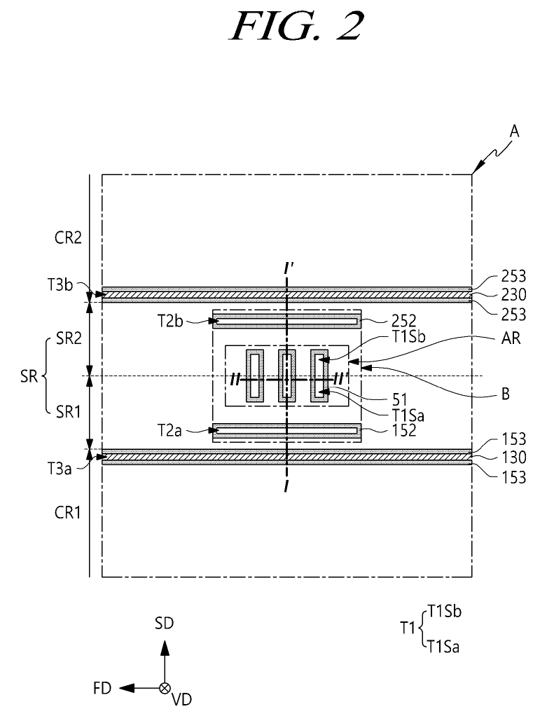

FIG. 2 is a plan view illustrating an embodiment of a semiconductor device, which is an enlarged view of the A region of FIG. 1.

The A region may include a partial region of the first semiconductor device and a partial region of the second semiconductor device.

Referring to FIG. 2, the first semiconductor device may include a first chip region CR1 and a portion of a first scribe lane region SR1 continuous with the first chip region CR1.

The first chip region CR1 may include a first guard ring 130. The first guard ring 130 may extend to surround an edge of the first chip region CR1.

A first guard trench T3a may be disposed on the first guard ring 130. A first guard buffer layer 153 may be disposed on a top surface of the first guard ring 130. The first guard buffer layer 153 may be disposed along sidewalls of the first guard trench T3a, although it is not limited thereto.

Although only one first guard ring 130 is illustrated in the first chip region CR1 in FIG. 2, the first chip region CR1 is not necessarily limited thereto and may include various numbers of the first guard ring 130.

A first buffer trench T2a may be disposed on the first scribe lane region SR1. The first buffer trench T2a may be located between the key trench T1 and the first guard ring 130. A first trench buffer layer 152 may be disposed inside the first buffer trench T2a. The first trench buffer layer 152 may be disposed along a sidewall of the first buffer trench T2a. The first buffer trench T2a may extend along the first direction FD.

Referring to FIG. 2, a second semiconductor device may include a second chip region CR2 and a portion of a second scribe lane region SR2 continuous with the second chip region CR2.

The second chip region CR2 may include a second guard ring 230. The second guard ring 230 may extend to surround an edge of the second chip region CR2.

A second guard trench T3b may be disposed on the second guard ring 230. A second guard buffer layer 253 may be disposed on an upper surface of the second guard ring 230. The second guard buffer layer 253 may be disposed along a sidewall of the second guard trench T3b, although it is not limited thereto.

Although only one second guard ring 230 is shown in the second chip region CR2 in FIG. 2, it is not necessarily limited thereto, and the second chip region CR2 may include a plurality of second guard rings 230.

A second buffer trench T2b may be disposed on the second scribe lane region SR2. The second buffer trench T2b may be located between the key trench T1 and the second guard ring 230. A second trench buffer layer 252 may be disposed inside the second buffer trench T2b. The second trench buffer layer 252 may be disposed along a sidewall of the second buffer trench T2b. The second buffer trench T2b may extend along the first direction FD.

In an embodiment, the combined width of the first and second scribe lanes SR1 and SR2 may range between about 25 um to 75 um, e.g., about 50 um.

An alignment key region AR may be disposed on the scribe lane region SR. The key trench T1 may be located within the alignment key region AR. An alignment pattern layer 51 may be disposed inside the key trench T1. In an embodiment, the key trench T1 has a dimension ranging from 2 um to 6 um (e.g., about 4 um) in width to 15 um to about 70 um (e.g., about 34 um) in length. [CORRECT?] In one embodiment, the alignment pattern layer 51 may be part of a redistribution alignment key. The redistribution alignment key may be used for alignment for etching a redistribution pattern layer during a manufacturing process of the semiconductor device.

In an embodiment, the redistribution pattern layer connects a metal layer (e.g., typically the top metal layer or the uppermost metal interconnect layer) to a new layout suited for external nodes, such as solder bumps or under-bump metallization (UBM). Such a redistribution facilitates more reliable and accessible electrical connections to a package substrate or to other chips in a multi-chip module. In an implementation, the redistribution pattern layer includes or uses aluminum.

In an embodiment, the redistribution pattern layer is formed in a redistribution via (RDV) that is formed on or above the top metal layer. The RDV is configured to support signal redistribution, power delivery, or mechanical connectivity in packaging.

The key trench T1 may include a first key trench segment T1Sa and a second key trench segment T1Sb. In an embodiment, these segments are continuous prior to separation of the chips by dicing. As shown in FIG. 2, a plurality of key trenches T1 may be disposed in the scribe lane region SR. A plurality of first key trench segments T1Sa may be disposed in the first scribe lane region SR1. A plurality of second key trench segments T1Sb may be disposed in the second scribe lane region SR2.

At least one first buffer trench T2a may be located between the first chip region CR1 and the plurality of first key trench segments T1Sa. At least one second buffer trench T2b may be located between the second chip region CR2 and the plurality of second key trench segments T1Sb.

One side surface of the at least one first buffer trench T2a may be adjacent to (e.g., facing) one side surface of each of the plurality of first key trench segments T1Sa. The plurality of first key trench segments T1Sa may be located above and between one end and the other end of the at least one first buffer trench T2a. As understood by one skilled in the art, the term “above” as used herein in connection with the key trench segments may be interchanged with “below,” depending on the viewing orientation relative to the buffer trench. A bottom surface of the at least one first buffer trench T2a may be located on or about the same plane as a bottom surface of each of the plurality of first key trench segments T1Sa. In an embodiment, a bottom surface of the first buffer trench T2a is approximately level with, or extends slightly below, the bottom surface of one or more of the first key trench segments T1Sa, thereby helping to interrupt crack propagation paths toward the chip region during dicing.

A length of the at least one first buffer trench T2a in the first direction FD may be greater than a length of each of the plurality of first key trench segments T1Sa in the first direction FD. A length of the at least one first buffer trench T2a in the second direction SD may be smaller than a length of each of the plurality of first key trench segments T1Sa in the second direction SD.

One side surface of the at least one second buffer trench T2b may be adjacent to (e.g., facing) one side surface of each of the plurality of second key trench segments T1Sb. The plurality of second key trench segments T1Sb may be located below and between one end and the other end of the at least one second buffer trench T2b. A bottom surface of the at least one second buffer trench T2b may be located on the same plane as a bottom surface of each of the plurality of second key trench segments T1Sb. As understood by one skilled in the art, the term “below” as used herein in connection with the key trench segments may be interchanged with “above,” depending on the viewing orientation relative to the buffer trench.

A length of the at least one second buffer trench T2b in the first direction FD may be greater than a length of each of the plurality of second key trench segments T1Sb in the first direction FD. A length of the at least one second buffer trench T2b in the second direction SD may be smaller than a length of each of the plurality of second key trench segments T1Sb in the second direction SD.

Although three key trenches T1 are shown in the alignment key region AR in FIG. 2, the alignment key region AR is not necessarily limited thereto and may include a plurality of key trenches T1.

In one embodiment, the key trench T1 may be disposed in a bar shape on a plane defined by the first direction FD and the second direction SD, as shown in FIG. 2, but is not necessarily limited thereto.

A region including the key trench T1 and the buffer trenches T2a and T2b may be defined as a region B.

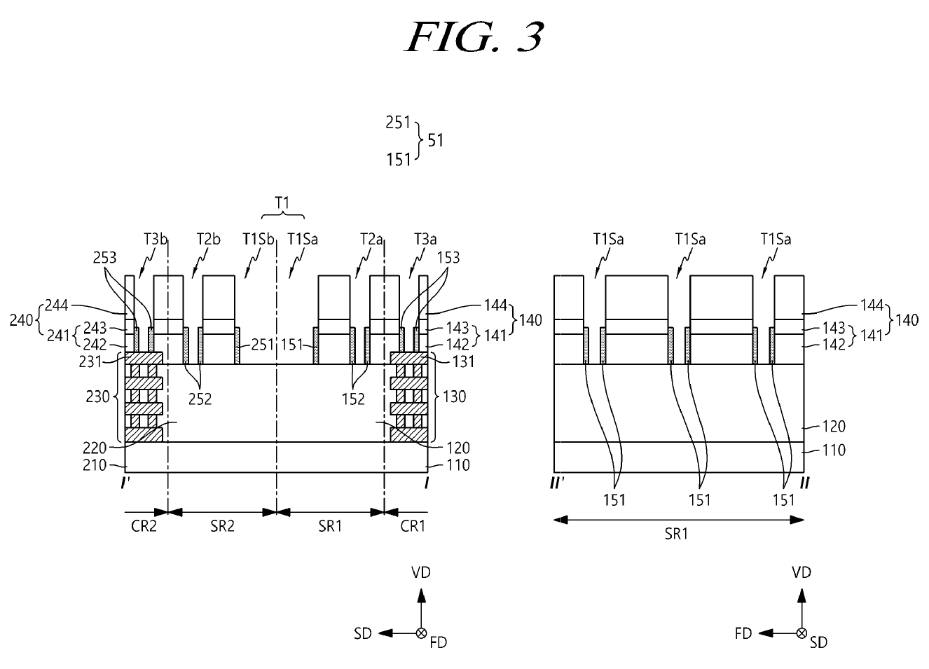

FIG. 3 illustrates examples of a cross-sectional structure taken along line I–I′ and a cross-sectional structure taken along line II–II′ of FIG. 2.

Referring to FIG. 3, the first semiconductor device may include a first substrate 110, a first element layer 120, a first guard ring 130, a first insulation structure 140, a first alignment pattern layer 151, a first trench buffer layer 152, and a first guard buffer layer 153.

The first substrate 110 may be located in the first chip region CR1 and the first scribe lane region SR1.

The first element layer 120 and the first guard ring 130 may be disposed on the first substrate 110.

The first substrate 110 may include a semiconductor substrate such as a silicon wafer or a Silicon On Insulator (SOI) wafer. The first substrate 110 may include a Group III–V semiconductor substrate, such as a compound semiconductor substrate like GaAs. The first substrate 110 may include single-crystal silicon, polysilicon, amorphous silicon, single-crystal silicon germanium, polycrystalline silicon germanium, carbon-doped silicon, or a combination thereof.

The first element layer 120 may include at least two elements selected from the group consisting of silicon (Si), oxygen (O), nitrogen (N), carbon (C), boron (B), phosphorus (P), and hydrogen (H). The first element layer 120 may include an insulating material having excellent step coverage and gap-fill characteristics.

The first guard ring 130 may include a plurality of guard pattern layers and guard contacts connecting the guard pattern layers. In one embodiment, the guard pattern layer and the guard contact may include tungsten (W), tungsten nitride (WN), titanium (Ti), titanium nitride (TiN), aluminum (Al), copper (Cu), tantalum (Ta), tantalum nitride (TaN), gold (Au), or a combination of two or more thereof.

Among the guard pattern layers included in the first guard ring 130, a guard pattern layer located at an uppermost part may be defined as a first guard pattern layer 131. The first guard pattern layer 131 may be located on the first element layer 120. The first guard pattern layer 131 may surround the first chip region CR1.

Referring also to FIG. 2, a plurality of first key trench segments T1Sa may be disposed outside the first guard pattern layer 131. At least one first buffer trench T2a may be disposed between the first guard pattern layer 131 and the plurality of first key trench segments T1Sa.

The first insulation structure 140 may include a first passivation layer 141 and a first redistribution insulation layer 144. The first redistribution insulation layer 144 may be located on the first passivation layer 141.

The first passivation layer 141 may include a high-density plasma (HDP) oxide, a nitride, or a combination thereof. The first passivation layer 141 may include a first passivation oxide layer 142 and a first passivation nitride layer 143. The first passivation nitride layer 143 may be located on the first passivation oxide layer 142. In one embodiment, the first passivation oxide layer 142 may include a high-density plasma oxide.

The first redistribution insulation layer 144 may include silicon oxide, silicon nitride, silicon oxynitride, low-k dielectrics, high-k dielectrics, or a combination thereof. In one embodiment, the first redistribution insulation layer 144 may include an oxide.

The key trench T1 may include a first key trench segment T1Sa. The first key trench segment T1Sa may be formed after the wafer 1 is diced. The first key trench segment T1Sa may penetrate the first insulation structure 140. The first key trench segment T1Sa may be located on the first scribe lane region SR1. The first key trench segment T1Sa may be disposed along the first direction FD.

A first alignment pattern layer 151 may be disposed inside the first key trench segment T1Sa. In one embodiment, the first alignment pattern layer 151 may cover part of a sidewall and a bottom surface of the first key trench segment T1Sa, but is not necessarily limited thereto.

The first alignment pattern layer 151 may include tungsten (W), tungsten nitride (WN), titanium (Ti), titanium nitride (TiN), aluminum (Al), copper (Cu), tantalum (Ta), tantalum nitride (TaN), gold (Au), or a combination of two or more thereof. In one embodiment, the first alignment pattern layer 151 may include aluminum (Al).

The first buffer trench T2a may be located on the first scribe lane region SR1. The first buffer trench T2a may be located on the first element layer 120. The first buffer trench T2a may penetrate the first insulation structure 140.

A depth of the at least one first buffer trench T2a may be the same as a depth of each of the plurality of first key trench segments T1Sa.

A first trench buffer layer 152 may be disposed inside the first buffer trench T2a. In one embodiment, the first trench buffer layer 152 may cover parts of a sidewall and a bottom surface of the first buffer trench T2a, but is not necessarily limited thereto.

In an embodiment, the first trench buffer layer 152 may assist in interrupting crack propagation paths during wafer dicing. For example, the first trench buffer layer 152 may act as a physical barrier or an energy-absorbing structure, or both.

The first trench buffer layer 152 may include tungsten (W), tungsten nitride (WN), titanium (Ti), titanium nitride (TiN), aluminum (Al), copper (Cu), tantalum (Ta), tantalum nitride (TaN), gold (Au), or a combination of two or more thereof. In one embodiment, the first trench buffer layer 152 may include aluminum (Al).

A first guard trench T3a may be located on the first chip region CR1. The first guard trench T3a may be located on the first guard pattern layer 131.

A first guard buffer layer 153 may be disposed inside the first guard trench T3a. In one embodiment, the first guard buffer layer 153 may cover parts of a sidewall and a bottom surface of the first guard trench T3a, but is not necessarily limited thereto.

In one embodiment, the first guard buffer layer 153 may include substantially the same material as the first trench buffer layer 152.

Referring to FIG. 3, the second semiconductor device may include a second substrate 210, a second element layer 220, a second guard ring 230, a second insulation structure 240, a second alignment pattern layer 251, a second trench buffer layer 252, and a second guard buffer layer 253.

The second substrate 210 may be located in the second chip region CR2 and the second scribe lane region SR2.

A second element layer 220 and a second guard ring 230 may be disposed on a second substrate 210.

The second substrate 210 may include substantially the same material as the first substrate 110. The second element layer 220 may include substantially the same material as the first element layer 120.

A plurality of second key trench segments T1Sb may be disposed outside a second guard pattern layer 231. At least one second buffer trench T2b may be disposed between the second guard pattern layer 231 and the plurality of second key trench segments T1Sb.

The second guard ring 230 may include a plurality of guard pattern layers and guard metal contacts connecting the guard pattern layers. The second guard ring 230 may include substantially the same material as the first guard ring 130.

Among the guard pattern layers included in the second guard ring 230, a guard pattern layer located at an uppermost part may be defined as a second guard pattern layer 231. The second guard pattern layer 231 may be located on the second element layer 220. The second guard pattern layer 231 may surround the second chip region CR2.

A second insulation structure 240 may include a second passivation layer 241 and a second redistribution insulation layer 244. The second redistribution insulation layer 244 may be located on the second passivation layer 241.

The second passivation layer 241 may include substantially the same material as the first passivation layer 141. The second passivation layer 241 may include a second passivation oxide layer 242 and a second passivation nitride layer 243. The second passivation nitride layer 243 may be located on the second passivation oxide layer 242. In one embodiment, the second passivation oxide layer 242 may include substantially the same material as the first passivation oxide layer 142.

The second redistribution insulation layer 244 may include substantially the same material as the first redistribution insulation layer 144.

The key trench T1 may include a second key trench segment T1Sb. The second key trench segment T1Sb may be formed after the wafer 1 is diced. The second key trench segment T1Sb may penetrate the second insulation structure 240. The second key trench segment T1Sb may be located on the second scribe lane region SR2. The second key trench segment T1Sb may be disposed along the first direction FD.

A second alignment pattern layer 251 may be disposed inside the second key trench segment T1Sb. In one embodiment, the second alignment pattern layer 251 may cover parts of a sidewall and a bottom surface of the second key trench segment T1Sb, but is not necessarily limited thereto.

In one embodiment, the second alignment pattern layer 251 may include substantially the same material as the first alignment pattern layer 151.

The second buffer trench T2b may be located on the second scribe lane region SR2. The second buffer trench T2b may be located on the second element layer 220. The second buffer trench T2b may penetrate the second insulation structure 240.

A depth of the at least one second buffer trench T2b may be the same as a depth of each of the plurality of second key trench segments T1Sb.

A second trench buffer layer 252 may be disposed inside the second buffer trench T2b. In one embodiment, the second trench buffer layer 252 may cover parts of a sidewall and a bottom surface of the second buffer trench T2b, but is not necessarily limited thereto.

In one embodiment, the second trench buffer layer 252 may include substantially the same material as the first trench buffer layer 152.

A second guard trench T3b may be located on the second chip region CR2. The second guard trench T3b may be located on the second guard pattern layer 231.

A second guard buffer layer 253 may be disposed inside the second guard trench T3b. In one embodiment, the second guard buffer layer 253 may cover part of a sidewall and a bottom surface of the second guard trench T3b, but is not necessarily limited thereto.

In one embodiment, the second guard buffer layer 253 may include substantially the same material as the first guard buffer layer 153.

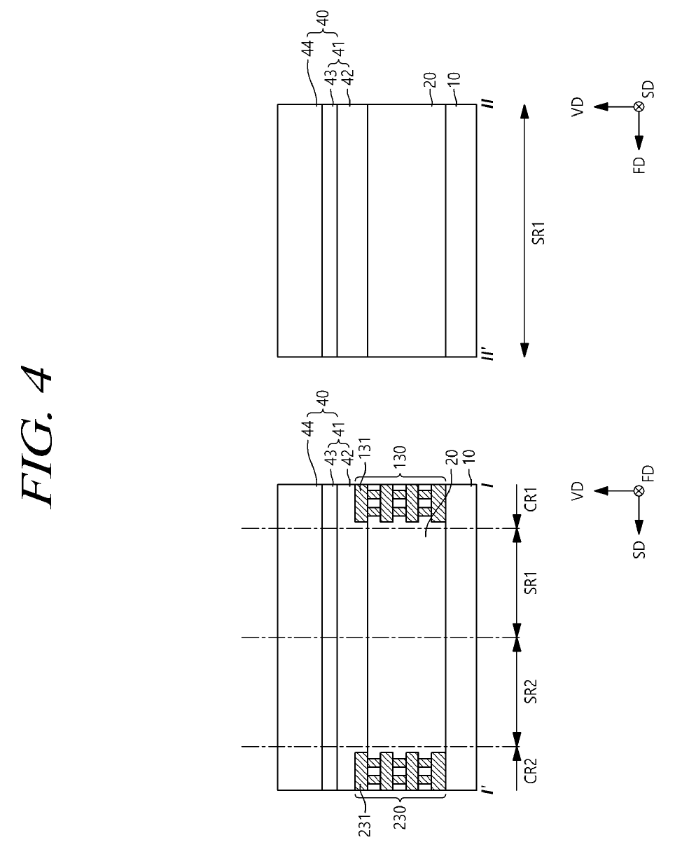

FIGS. 4-8 are cross-sectional views or plan views enlarged from a region B, illustrating a method of manufacturing a semiconductor device according to the embodiment disclosed in FIG. 2.

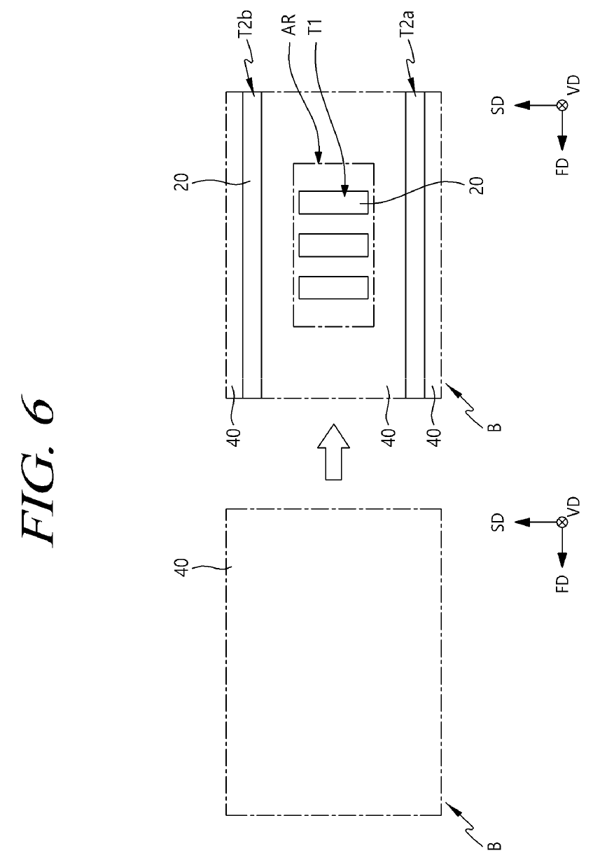

FIG. 4 is a cross-sectional view illustrating a method of manufacturing a semiconductor device according to the embodiment disclosed in FIG. 2. FIG. 6 is a plan view enlarged from the region B, illustrating a method of manufacturing a semiconductor device according to the embodiment disclosed in FIG. 2.

Referring to FIG. 4, an element layer 20 and guard rings 130 and 230 may be formed on the substrate 10. The first guard ring 130 may be formed on the first chip region CR1. The second guard ring 230 may be formed on the second chip region CR2. A first guard pattern layer 131 may be located on the element layer 20. A second guard pattern layer 231 may be located on the element layer 20.

Referring to FIGS. 4 and 6, an insulation structure 40 may be formed on the element layer 20. The insulation structure 40 may include a passivation layer 41 and a redistribution insulation layer 44. The passivation layer 41 may include a passivation oxide layer 42 and a passivation nitride layer 43. The passivation oxide layer 42 may be located on the element layer 20. The passivation nitride layer 43 may be located on the passivation oxide layer 42. The redistribution insulation layer 44 may be located on the passivation nitride layer 43.

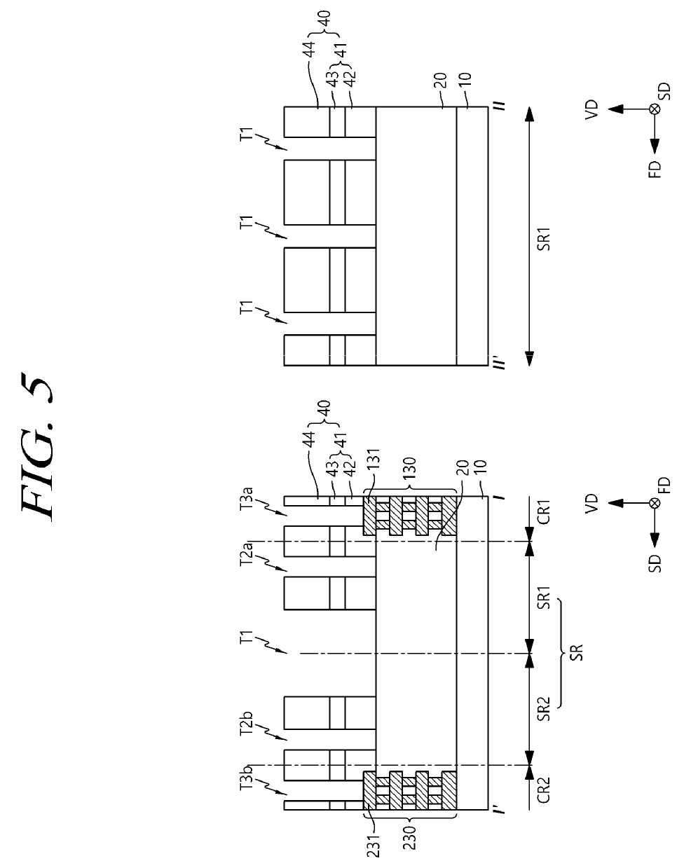

FIG. 5 is a cross-sectional view illustrating a method of manufacturing a semiconductor device according to the embodiment disclosed in FIG. 2.

Referring to FIGS. 5 and 6, a key trench T1 may be formed in a scribe lane region SR. The key trench T1 may be located within an alignment key region AR. The key trench T1 may be formed by anisotropic etching. In one embodiment, the key trench T1 may have a bar shape, but is not necessarily limited thereto. The key trench T1 may penetrate the insulation structure 40. As the key trench T1 is formed, a portion of a top surface of the element layer 20 may be exposed. A bottom surface of the key trench T1 may be on the same plane as the top surface of the element layer 20.

A first buffer trench T2a may be formed in the first scribe lane region SR1. The first buffer trench T2a may be formed by anisotropic etching. The first buffer trench T2a may penetrate the insulation structure 40. As the first buffer trench T2a is formed, a portion of the top surface of the element layer 20 may be exposed. A bottom surface of the first buffer trench T2a may be on the same plane as the top surface of the element layer 20.

A first guard trench T3a may be formed in the first chip region CR1. The first guard trench T3a may be formed by anisotropic etching. As the first guard trench T3a is formed, a portion of the top surface of the first guard pattern layer 131 may be exposed. A bottom surface of the first guard trench T3a may be on the same plane as the top surface of the first guard pattern layer 131.

A second buffer trench T2b may be formed in the second scribe lane region SR2. The second buffer trench T2b may be formed by anisotropic etching. The second buffer trench T2b may penetrate the insulation structure 40. As the second buffer trench T2b is formed, a portion of the top surface of the element layer 20 may be exposed. A bottom surface of the second buffer trench T2b may be on the same plane as the top surface of the element layer 20.

A second guard trench T3b may be formed in the second chip region CR2. The second guard trench T3b may be formed by anisotropic etching. As the second guard trench T3b is formed, a portion of the top surface of the second guard pattern layer 231 may be exposed. A bottom surface of the second guard trench T3b may be on the same plane as the top surface of the second guard pattern layer 231.

The buffer trenches T2a and T2b may have a bar shape, but are not necessarily limited thereto.

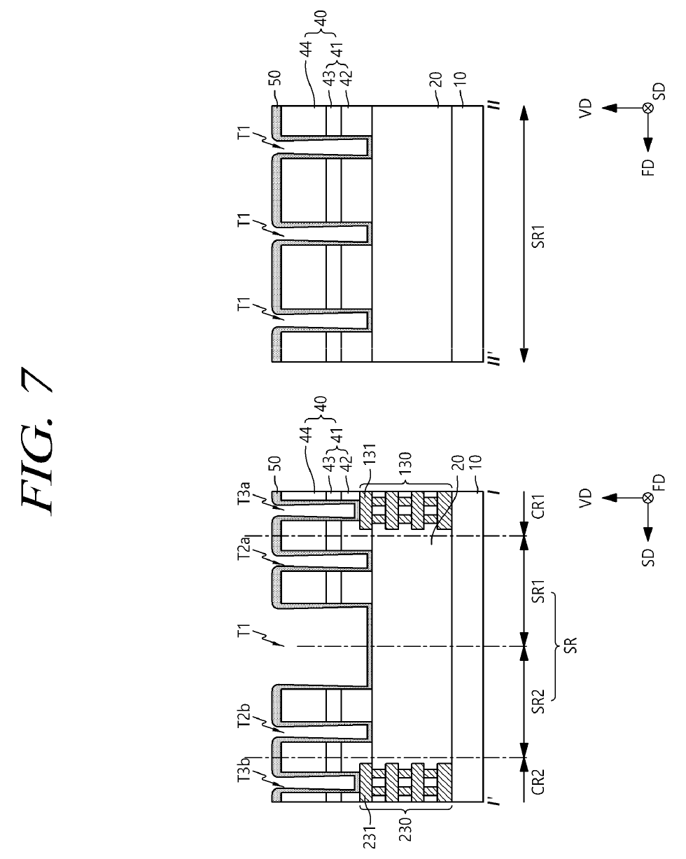

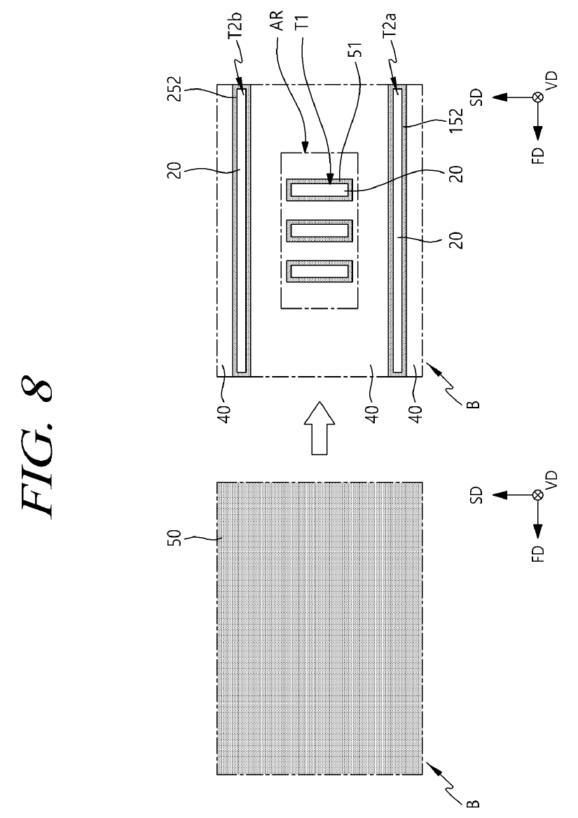

FIG. 7 is a cross-sectional view illustrating a method of manufacturing a semiconductor device according to the embodiment disclosed in FIG. 2. FIG. 8 is a plan view enlarged from a region B, illustrating a method of manufacturing a semiconductor device according to the embodiment disclosed in FIG. 2.

Referring to FIGS. 7 and 8, a redistribution material 50 may be deposited. The redistribution material 50 may be formed using a film-forming technique providing excellent step coverage, such as chemical vapor deposition (CVD), physical vapor deposition (PVD), or atomic layer deposition (ALD). In one embodiment, the redistribution material 50 may be deposited by physical vapor deposition (PVD).

As the redistribution material 50 is deposited, an overhang may be formed. The redistribution material 50 may include a conductive metal material such as copper (Cu) or aluminum (Al). In one embodiment, the redistribution material 50 may include aluminum (Al).

The redistribution material 50 may be deposited on the insulation structure 40. The redistribution material 50 may cover the key trench T1. The redistribution material 50 may cover the buffer trenches T2a and T2b. The redistribution material 50 may cover the guard trenches T3a and T3b.

Referring to FIGS. 3 and 8, the redistribution material 50 may be etched. An alignment pattern layer 51 may be formed in the scribe lane region SR. The alignment pattern layer 51 may be formed by an anisotropic etching process. As the alignment pattern layer 51 is formed, the top surface of the element layer 20 may be exposed. The alignment pattern layer 51 may be located inside the key trench T1.

A first trench buffer layer 152 may be formed in the first scribe lane region SR1. The first trench buffer layer 152 may be formed by an anisotropic etching process. As the first trench buffer layer 152 is formed, the top surface of the element layer 20 may be exposed. The first trench buffer layer 152 may be located inside the first buffer trench T2a.

A first guard buffer layer 153 may be formed in the first chip region CR1. The first guard buffer layer 153 may be formed by an anisotropic etching process. As the first guard buffer layer 153 is formed, the top surface of the first guard pattern layer 131 may be exposed. The first guard buffer layer 153 may be located inside the first guard trench T3a.

A second trench buffer layer 252 may be formed in the second scribe lane region SR2. The second trench buffer layer 252 may be formed by an anisotropic etching process. As the second trench buffer layer 252 is formed, the top surface of the element layer 20 may be exposed. The second trench buffer layer 252 may be located inside the second buffer trench T2b.

A second guard buffer layer 253 may be formed in the second chip region CR2. The second guard buffer layer 253 may be formed by an anisotropic etching process. As the second guard buffer layer 253 is formed, the top surface of the second guard pattern layer 231 may be exposed. The second guard buffer layer 253 may be located inside the second guard trench T3b.

As the trench buffer layers 152 and 252 are formed, they may function as a buffer even if a separation progresses laterally. Accordingly, the trench buffer layers 152 and 252 may protect the guard rings 130 and 230 even if the separation progresses laterally.

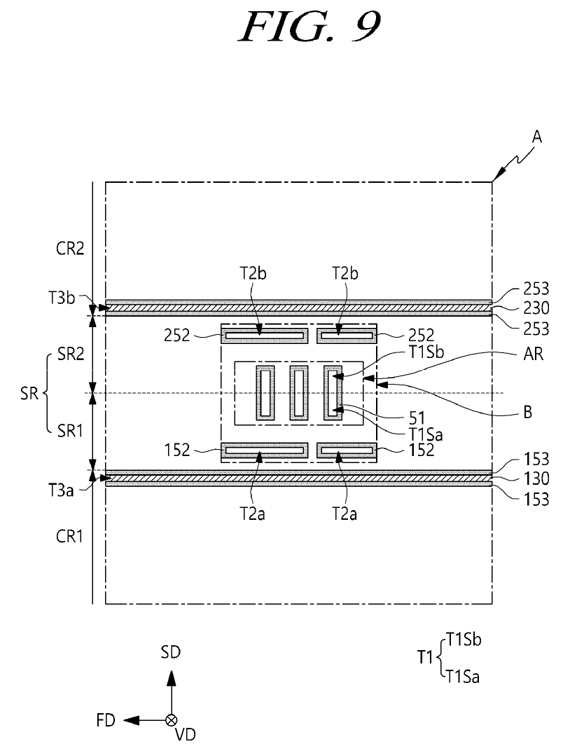

FIG. 9 is a plan view enlarged from a region A, illustrating another embodiment of a semiconductor device disclosed in FIG. 1.

In the following description of embodiments, explanations for components that are substantially the same as those in previous embodiments will be omitted.

A semiconductor device illustrated in FIG. 9 may be formed using the same method as the method of manufacturing the semiconductor device described with reference to FIGS. 3-7.

Referring to FIG. 9, a plurality of first buffer trenches T2a may be disposed in a first scribe lane region SR1. Although two first buffer trenches T2a are illustrated in FIG. 9, the number is not limited thereto. Adjacent first buffer trenches T2a may be spaced apart from each other.

A plurality of second buffer trenches T2b may be disposed in a second scribe lane region SR2. Although two second buffer trenches T2b are illustrated in FIG. 9, the number is not limited thereto. Adjacent second buffer trenches T2b may be spaced apart from each other.

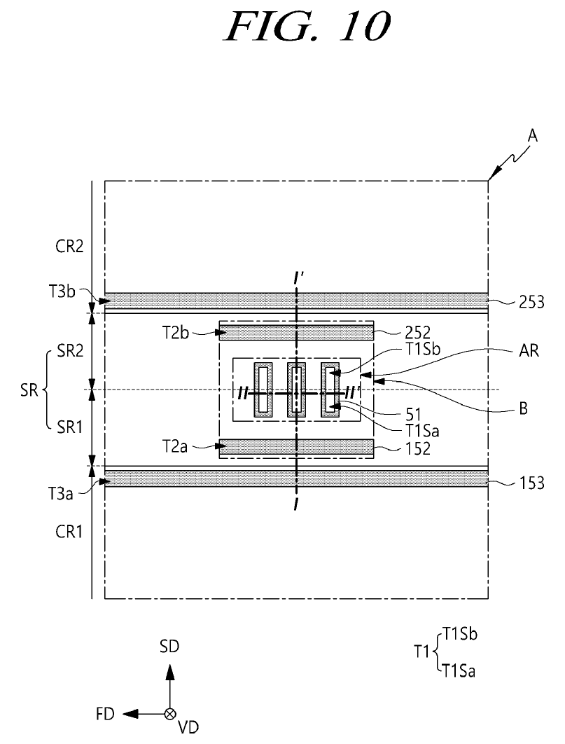

FIG. 10 is a plan view enlarged from a region A, illustrating another embodiment of a semiconductor device disclosed in FIG. 1.

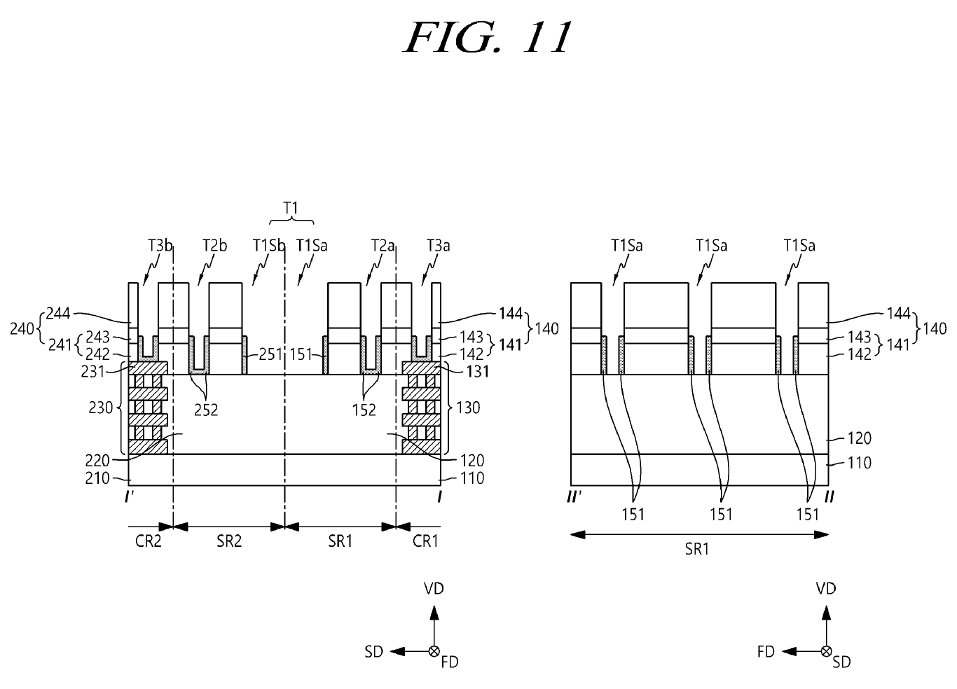

FIG. 11 is a diagram illustrating examples of cross-sectional structures taken along lines I-I′ and II-II′ of FIG. 10.

A semiconductor device illustrated in FIGS. 10 and 11 may be formed using the same method as the method of manufacturing the semiconductor device described with reference to FIGS. 4 and 7.

Referring to FIGS. 10 and 11, a first trench buffer layer 152 may cover a bottom surface of a first buffer trench T2a. A first guard buffer layer 153 may cover a bottom surface of a first guard trench T3a.

A second trench buffer layer 252 may cover a bottom surface of a second buffer trench T2b. A second guard buffer layer 253 may cover a bottom surface of a second guard trench T3b.

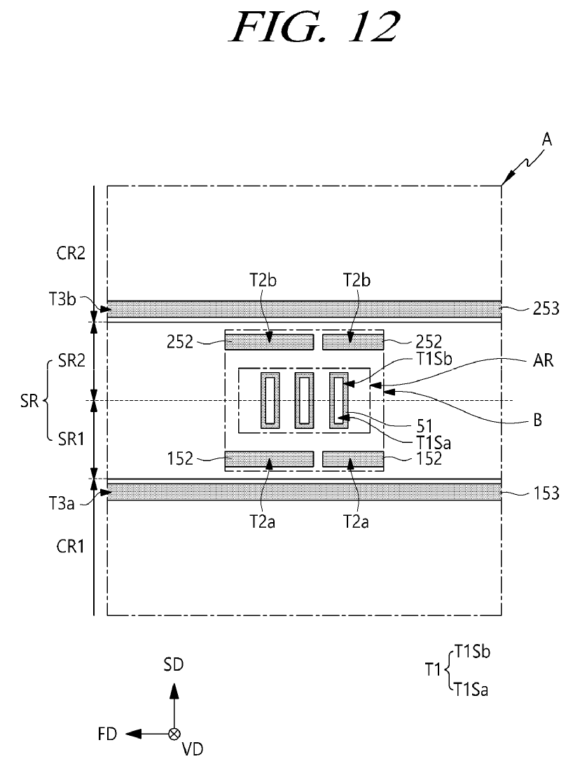

FIG. 12 is a plan view enlarged from a region A, illustrating another embodiment of a semiconductor device disclosed in FIG. 1.

A semiconductor device illustrated in FIG. 12 may be formed using the same method as the method of manufacturing the semiconductor device described with reference to FIGS. 4, 7, and 11.

Referring to FIGS. 12 and 11, a plurality of first buffer trenches T2a may be disposed in the first scribe lane region SR1. Although two first buffer trenches T2a are illustrated in FIG. 11, the number is not limited thereto. Adjacent first buffer trenches T2a may be spaced apart from each other.

The plurality of second buffer trenches T2b may be disposed in the second scribe lane region SR2. Although two second buffer trenches T2b are illustrated in FIG. 11, the number is not limited thereto. Adjacent second buffer trenches T2b may be spaced apart from each other.

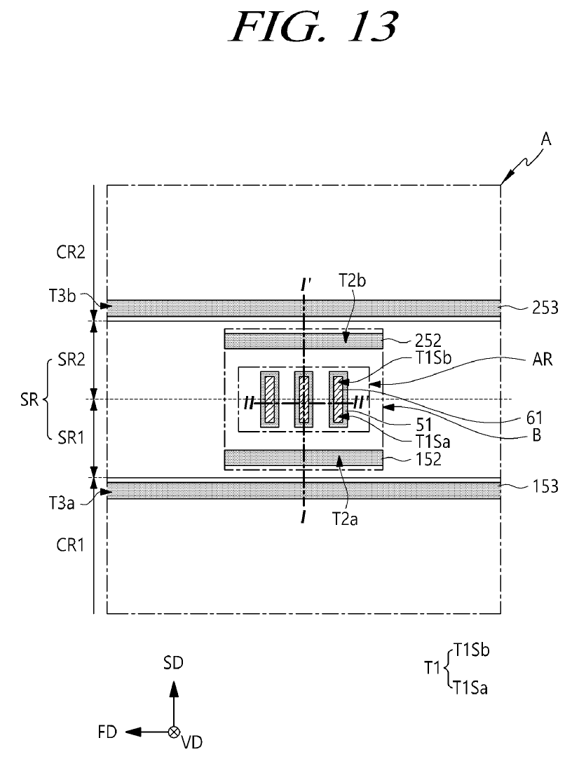

FIG. 13 is a plan view enlarged from a region A, illustrating another embodiment of a semiconductor device disclosed in FIG. 1.

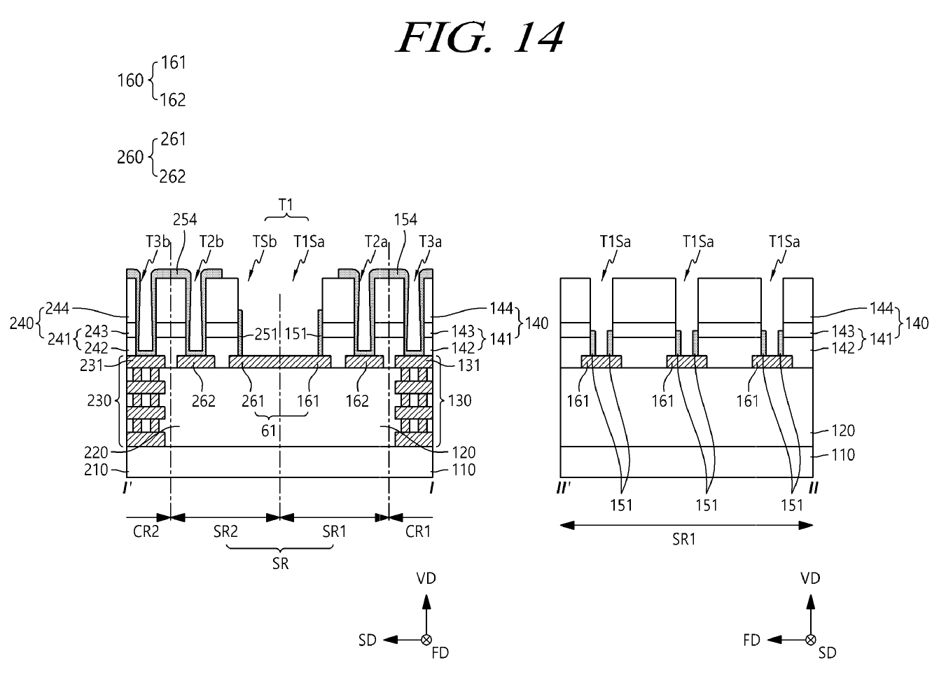

FIG. 14 is a diagram illustrating examples of cross-sectional structures taken along lines I-I′ and II-II′ of FIG. 13.

Referring to FIGS. 13 and 14, a first semiconductor device may further include a first dummy pattern layer 160. The first dummy pattern layer 160 may be located in a layer where a first guard pattern layer 131 is disposed. A top surface of the first dummy pattern layer 160 may be in contact with a bottom surface of at least one first buffer trench T2a. The top surface of the first dummy pattern layer 160 may be in contact with a bottom surface of each of a plurality of first key trench segments T1Sa. The first dummy pattern layer 160 may include a first key dummy pattern layer 161 and a first buffer dummy pattern layer 162.

A first key dummy pattern layer 161 may be disposed on the first element layer 120. The first key dummy pattern layer 161 may be located in the first scribe lane region SR1. The first key dummy pattern layer 161 may be located between the plurality of first key trench segments T1Sa and the first substrate 110.

A first buffer dummy pattern layer 162 may be disposed on the first element layer 120. The first buffer dummy pattern layer 162 may be located in the first scribe lane region SR1. The first buffer dummy pattern layer 162 may be located between at least one first buffer trench T2a and the first substrate 110. The first buffer dummy pattern layer 162 may be closer to the first chip region CR1 than the first key dummy pattern layer 161. A first dummy buffer layer 154 may be disposed on the first buffer dummy pattern layer 162.

A second semiconductor device may further include a second dummy pattern layer 260. The second dummy pattern layer 260 may be located in a layer where a second guard pattern layer 231 is disposed. A top surface of the second dummy pattern layer 260 may be in contact with a bottom surface of at least one second buffer trench T2b. The top surface of the second dummy pattern layer 260 may be in contact with a bottom surface of each of a plurality of second key trench segments T1Sb. The second dummy pattern layer 260 may include a second key dummy pattern layer 261 and a second buffer dummy pattern layer 262.

A second key dummy pattern layer 261 may be disposed on a second element layer 220. The second key dummy pattern layer 261 may be located in the second scribe lane region SR2. The second key dummy pattern layer 261 may be located between the plurality of second key trench segments T1Sb and a second substrate 210.

A second buffer dummy pattern layer 262 may be disposed on a second element layer 220. The second buffer dummy pattern layer 262 may be located in a second scribe lane region SR2. The second buffer dummy pattern layer 262 may be located between at least one second buffer trench T2b and a second substrate 210. The second buffer dummy pattern layer 262 may be closer to a second chip region CR2 than a second key dummy pattern layer 261. A second dummy buffer layer 254 may be disposed on the second buffer dummy pattern layer 262.

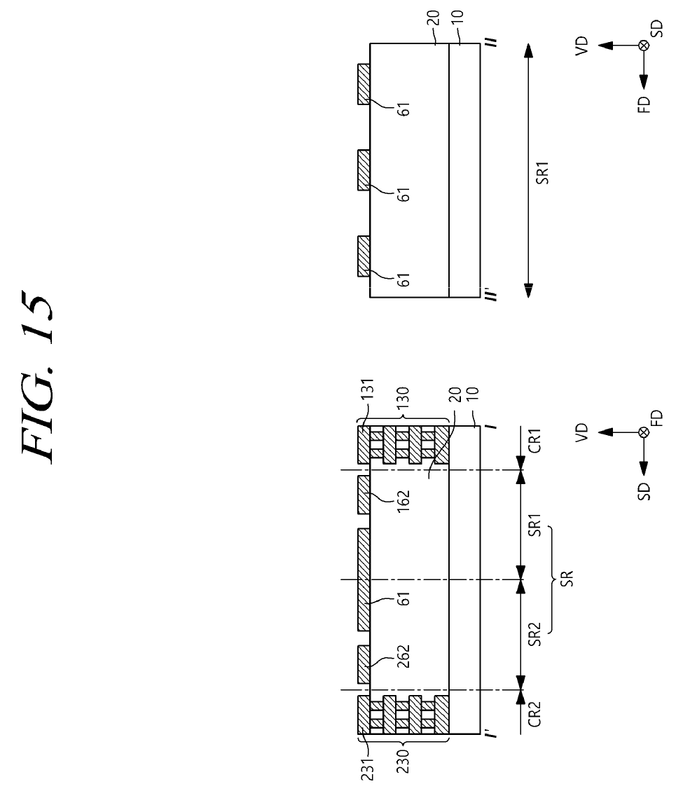

FIGS. 15-20 are cross-sectional views or plan views enlarged from a region B, illustrating examples of a method of manufacturing a semiconductor device according to the embodiment disclosed in FIG. 13.

Referring to FIG. 15, a key dummy pattern layer 61 may be formed on an element layer 20. Buffer dummy pattern layers 162 and 262 may be formed on the element layer 20. The key dummy pattern layer 61 may be formed in a scribe lane region SR. The first buffer dummy pattern layer 162 may be formed in a first scribe lane region SR1. The second buffer dummy pattern layer 262 may be formed in a second scribe lane region SR2.

During a subsequent etching process, the element layer 20 may be etched. The key dummy pattern layer 61 may prevent the element layer 20 from being etched. The buffer dummy pattern layers 162 and 262 may prevent the element layer 20 from being etched.

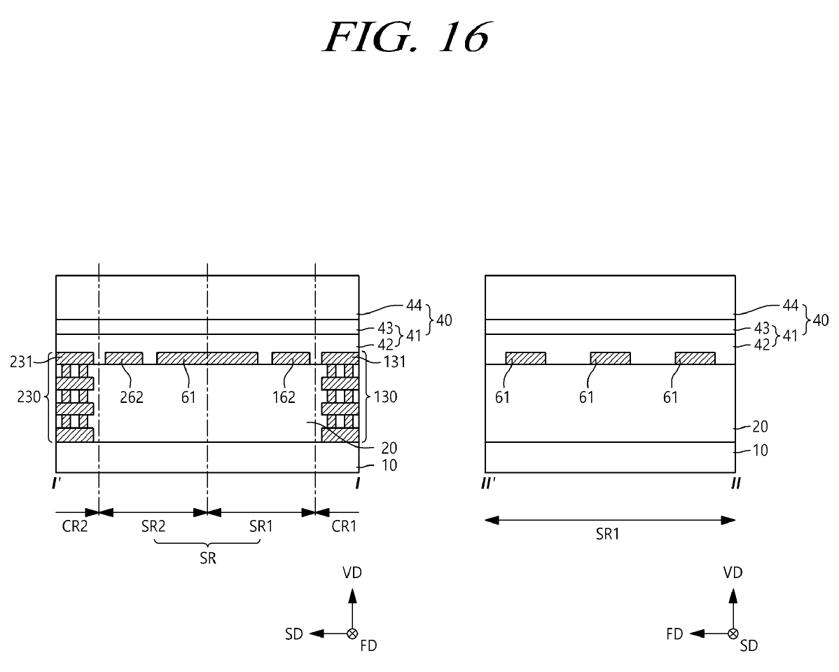

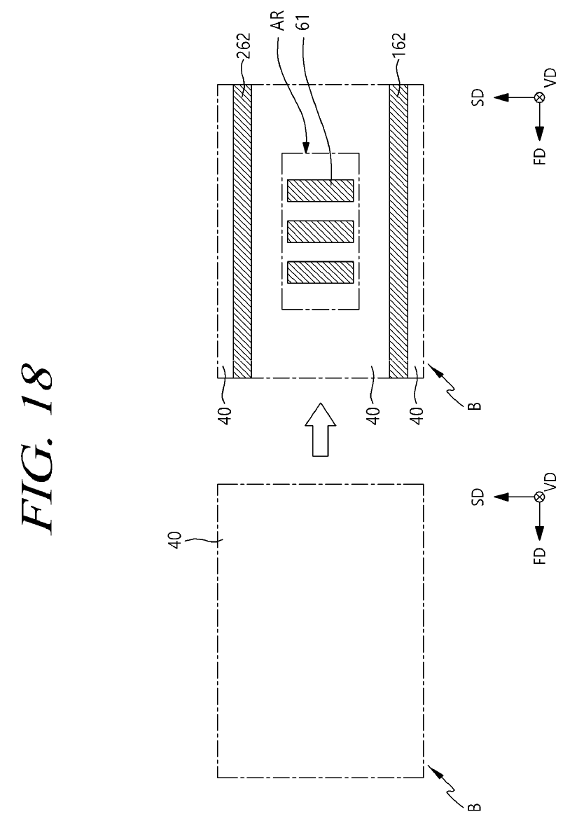

Referring to FIGS. 16 and 18, an insulating structure 40 may be formed on the element layer 20. The insulating structure 40 may include a passivation layer 41 and a redistribution insulating layer 44. The passivation layer 41 may cover the key dummy pattern layer 61 and the buffer dummy pattern layers 162 and 262.

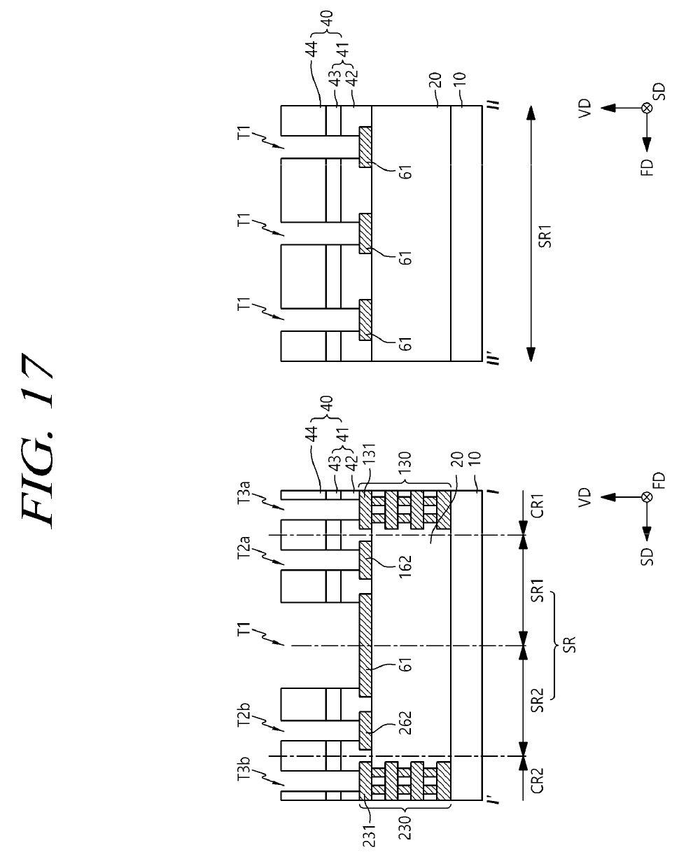

Referring to FIGS. 17 and 18, a key trench T1 may be formed in the scribe lane region SR. As the key trench T1 is formed, a portion of a top surface of the key dummy pattern layer 61 may be exposed. A bottom surface of the key trench T1 may be on the same plane as the top surface of the key dummy pattern layer 61.

A first buffer trench T2a may be formed in the first scribe lane region SR1. As the first buffer trench T2a is formed, a portion of a top surface of the first buffer dummy pattern layer 162 may be exposed. A bottom surface of the first buffer trench T2a may be on the same plane as the top surface of the first buffer dummy pattern layer 162.

A second buffer trench T2b may be formed in the second scribe lane region SR2. As the second buffer trench T2b is formed, a portion of a top surface of the second buffer dummy pattern layer 262 may be exposed. A bottom surface of the second buffer trench T2b may be on the same plane as the top surface of the second buffer dummy pattern layer 262.

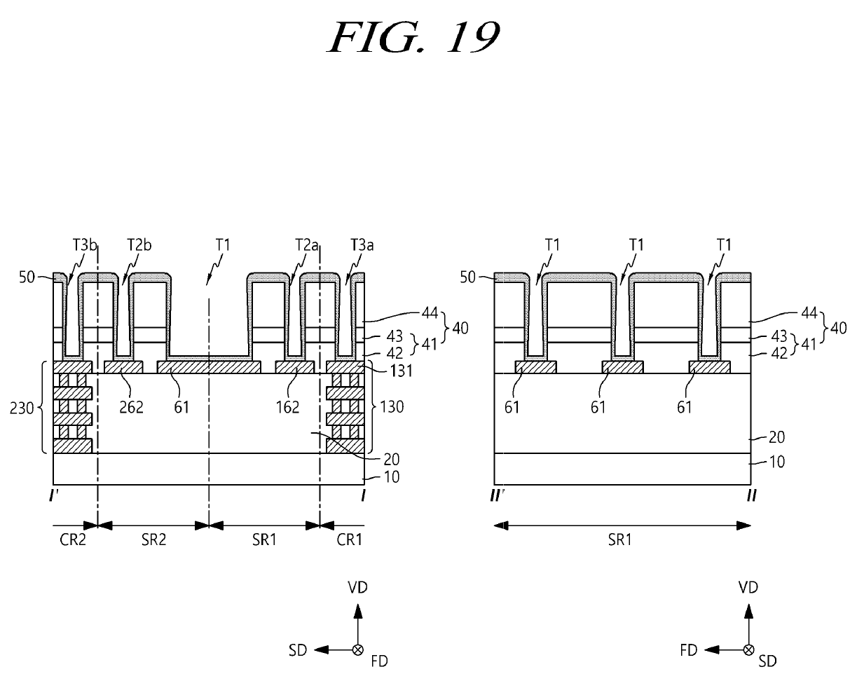

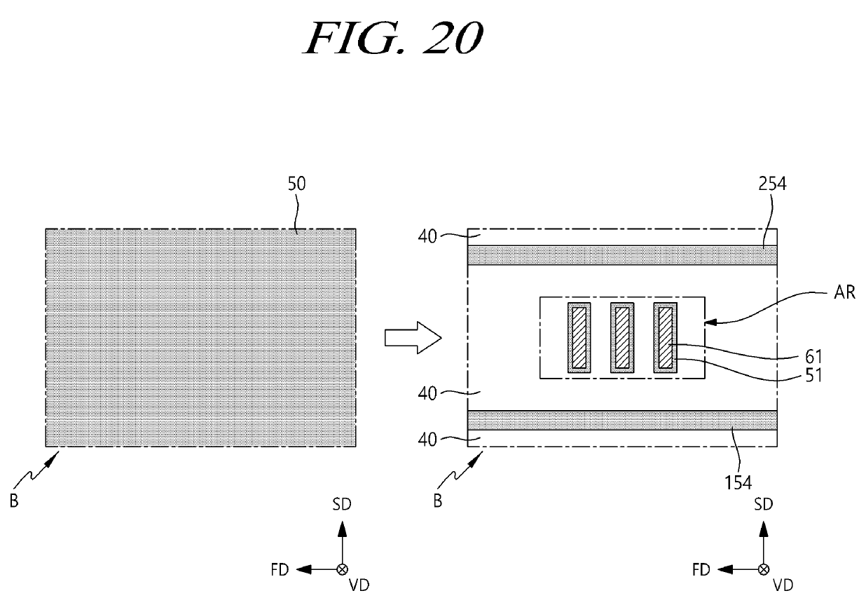

Referring to FIGS. 19 and 20, the redistribution material 50 may be deposited.

The redistribution material 50 may be deposited on the insulating structure 40. The redistribution material 50 may cover the key trench T1. The redistribution material 50 may cover the buffer trenches T2a and T2b. The redistribution material 50 may cover the guard trenches T3a and T3b.

Referring to FIGS. 14 and 20, the redistribution material 50 may be etched. An alignment pattern layer 51 may be formed in the scribe lane region SR. As the alignment pattern layer 51 is formed, the top surface of the key dummy pattern layer 61 may be exposed.

The first dummy buffer layer 154 may be formed in the first scribe lane region SR1. The first dummy buffer layer 154 may be formed to cover a bottom surface of the first buffer trench T2a. The first dummy buffer layer 154 may be formed to cover a bottom surface of the first guard trench T3a.

The second dummy buffer layer 254 may be formed in the second scribe lane region SR2. The second dummy buffer layer 254 may be formed to cover a bottom surface of the second buffer trench T2b. The second dummy buffer layer 254 may be formed to cover a bottom surface of the second guard trench T3b.

Since the region where the buffer trenches T2a and T2b are disposed is not etched during the etching of the redistribution material 50, the dummy buffer layers 154 and 254 may be formed. The dummy buffer layers 154 and 254 may serve as buffers even if chipping occurs in a lateral direction during a dicing process, thereby protecting a chip.

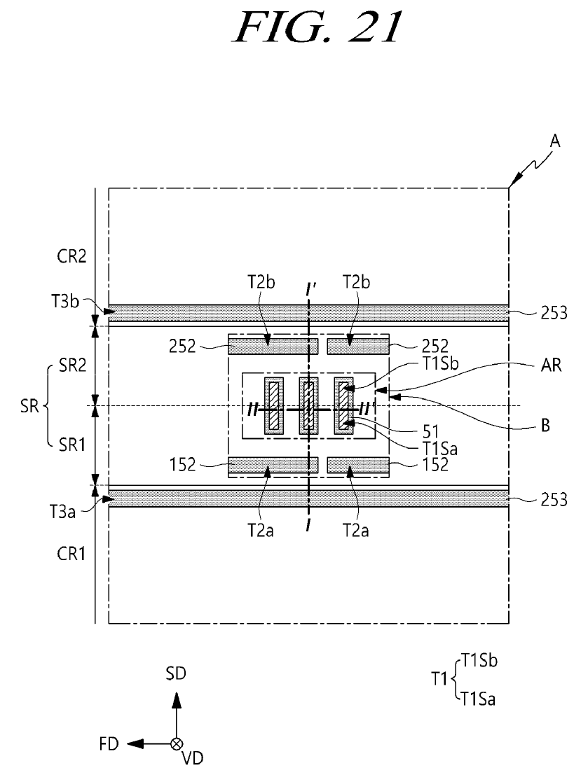

FIG. 21 is a plan view enlarged from a region A, illustrating another embodiment of a semiconductor device disclosed in FIG. 1.

A semiconductor device illustrated in FIG. 21 may be formed using the same method as the method of manufacturing the semiconductor device described with reference to FIGS. 14-17 and 19.

Referring to FIGS. 21 and 14, a plurality of first buffer trenches T2a may be disposed in the first scribe lane region SR1. Although two first buffer trenches T2a are illustrated in FIG. 21, the number is not limited thereto. Adjacent first buffer trenches T2a may be spaced apart from each other.

The first dummy buffer layer 154 may cover a bottom surface of the first buffer trench T2a. The first dummy buffer layer 154 may cover a bottom surface of the first guard trench T3a.

A plurality of second buffer trenches T2b may be disposed in the second scribe lane region SR2. Although two second buffer trenches T2b are illustrated in FIG. 21, the number is not limited thereto. Adjacent second buffer trenches T2b may be spaced apart from each other.

The second dummy buffer layer 254 may cover a bottom surface of the second buffer trench T2b. The second dummy buffer layer 254 may cover a bottom surface of the second guard trench T3b.

As described above, embodiments of the present disclosure relate to, among other features, preventing crack propagation toward the chip region during wafer singulation. Dense structures in alignment key regions located within scribe lanes may generate stress concentrations that may induce crack propagation in a direction perpendicular to the sawing direction, potentially extending into the chip region or resulting in irregular, jagged die edges. One or more buffer trenches are formed between the key region and the chip region to act as a mechanical mitigation structure that interrupts or absorbs stress propagation.

The following embodiments are presented as additional illustrative examples of the present disclosure and are intended to support claim variations that may be pursued in this or a related application.

Embodiments of the present disclosure may provide a semiconductor device, comprising: a substrate including a chip region and a scribe lane region; a guard ring disposed in the chip region; a key trench segment disposed in the scribe region; and a buffer trench disposed between the guard ring and the key trench segment, the buffer trench being configured to reduce mechanical stress transmission or mitigate crack propagation from the key trench segment toward the chip region during wafer singulation.

Embodiments of the present disclosure may provide the semiconductor device wherein the key trench segment is part of a plurality of key trench segments arranged along a first direction.

Embodiments of the present disclosure may provide the semiconductor device further comprising: a trench buffer layer disposed within the buffer trench, the trench buffer layer including a material suitable for interrupting the crack propagation, wherein the trench buffer layer serves as a physical barrier or an energy-absorbing structure, or both.

Embodiments of the present disclosure may provide the semiconductor device, wherein a bottom surface of the buffer trench is approximately level with a bottom surface of the key trench segment.

Embodiments of the present disclosure may provide the semiconductor device, further comprising: a guard pattern layer disposed in the chip region, wherein the upper surface of the guard pattern layer is approximately above the bottom surface of the key trench segment.

Embodiments of the present disclosure may provide the semiconductor device, wherein the guard pattern layer is an uppermost component of the guard ring.

Embodiments of the present disclosure may provide a method of manufacturing a semiconductor device, comprising: providing a substrate including a scribe lane region and a chip region; forming a guard ring in the chip region; forming a key trench in the scribe lane region; and forming a buffer trench in the scribe lane region between the guard ring and the key trench, wherein the buffer trench is configured to reduce mechanical stress transmission or mitigate crack propagation from the key trench segment toward the chip region during wafer singulation.

The above description merely provides an illustrative explanation of the present disclosure. Accordingly, a person of ordinary skill in the art to which the present disclosure pertains can make various modifications and variations without departing from the essential characteristics of the present disclosure. In addition, the embodiments disclosed in the present disclosure are not intended to limit the scope of the present disclosure but rather to explain it. Therefore, the scope of the present disclosure should not be limited by the embodiments.

What is claimed is:

1. A semiconductor device, comprising:
a substrate including a chip region and a scribe lane region located outside the chip region;
a plurality of key trench segments disposed in the scribe lane region and arranged along a first direction; and
at least one buffer trench disposed in the scribe lane region and extending along the first direction, the buffer trench being located between the chip region and the plurality of key trench segments.

2. The semiconductor device according to claim 1,
wherein one side of the at least one buffer trench is facing an end of each of the plurality of key trench segments, the buffer trench being configured to reduce mechanical stress transmission or mitigate crack propagation from the key trench segment toward the chip region during wafer singulation.

3. The semiconductor device according to claim 1,
wherein the plurality of key trench segments is located between one end and the other end of the at least one buffer trench.

4. The semiconductor device according to claim 1,
wherein the plurality of key trench segments is located in regions other than regions corresponding to areas between the at least one buffer trench and an adjacent buffer trench.

5. The semiconductor device according to claim 1,
wherein the at least one buffer trench is offset from the chip region in a second direction orthogonal to the first direction, and
wherein a length of the at least one buffer trench measured along the second direction is less than a length of each of the plurality of key trench segments measured along the second direction.

6. The semiconductor device according to claim 1,
wherein a bottom surface of the at least one buffer trench is approximately at the same level as bottom surfaces of each of the plurality of key trench segments.

7. The semiconductor device according to claim 6, further comprising:
a guard pattern layer disposed in the chip region wherein the upper surface of the guard pattern layer is approximately above the bottom surfaces of each of the key trench segments.

8. The semiconductor device according to claim 1,
wherein a depth of the at least one buffer trench is approximately the same as a depth of each of the plurality of key trench segments.

9. The semiconductor device according to claim 1, further comprising:
at least one dummy pattern layer located between the substrate and a layer in which the at least one buffer trench or the plurality of key trench segments are disposed.

10. The semiconductor device according to claim 9, further comprising:
a guard pattern layer disposed in the layer where the dummy pattern layer is located, between the chip region and the at least one buffer trench.

11. The semiconductor device according to claim 10,
wherein an upper surface of the dummy pattern layer is in contact with a bottom surface of the at least one buffer trench or bottom surfaces of each of the plurality of key trench segments.

12. A semiconductor device, comprising:
a substrate including a chip region and a scribe lane region located outside the chip region;
a plurality of key trench segments disposed in the scribe lane region; and
a buffer trench disposed in the scribe lane region and located between the chip region and the plurality of key trench segments,
wherein a length of the buffer trench measured along a first direction is greater than a length of each of the plurality of key trench segments measured along the first direction.

13. The semiconductor device according to claim 12,
wherein one side of the buffer trench is facing one side of each of the plurality of key trench segments.

14. The semiconductor device according to claim 12,
wherein the plurality of key trench segments is located between one end and the other end of the buffer trench.

15. The semiconductor device according to claim 12,
wherein the plurality of key trench segments is located in regions other than a region between the buffer trench and an adjacent buffer trench.

16. The semiconductor device according to claim 12,
wherein a length of the buffer trench in a second direction intersecting the first direction is less than a length of each of the plurality of key trench segments in the second direction.

17. The semiconductor device according to claim 12,
wherein a bottom surface of the buffer trench is approximately level with bottom surfaces of each of the plurality of key trench segments.

18. The semiconductor device according to claim 12,
wherein a depth of the buffer trench is approximately equal to a depth of each of the plurality of key trench segments.

19. The semiconductor device according to claim 12, further comprising:
at least one dummy pattern layer located between the substrate and a layer in which the buffer trench or the plurality of key trench segments are disposed.

20. The semiconductor device according to claim 19, further comprising:
a guard pattern layer disposed in the layer where the dummy pattern layer is located, between the chip region and the buffer trench.

21. The semiconductor device according to claim 20,
wherein an upper surface of the dummy pattern layer is in contact with a bottom surface of the buffer trench or bottom surfaces of each of the plurality of key trench segments.

22. A semiconductor device, comprising:
a substrate including a chip region and a scribe lane region;
a guard ring disposed in the chip region;
a key trench segment disposed in the scribe region; and
a buffer trench disposed between the guard ring and the key trench segment, the buffer trench being configured to reduce mechanical stress transmission or mitigate crack propagation from the key trench segment toward the chip region during wafer singulation.

23. The semiconductor device according to claim 22, wherein the key trench segment is part of a plurality of key trench segments arranged along a first direction.

24. The semiconductor device according to claim 22, further comprising:
a trench buffer layer disposed within the buffer trench, the trench buffer layer including a material suitable for interrupting the crack propagation,
wherein the trench buffer layer serves as a physical barrier or an energy-absorbing structure, or both.

25. The semiconductor device according to claim 22, wherein a bottom surface of the buffer trench is approximately level with a bottom surface of the key trench segment.

26. The semiconductor device according to claim 25, further comprising:
a guard pattern layer disposed in the chip region,
wherein the upper surface of the guard pattern layer is approximately above the bottom surface of the key trench segment.

27. The semiconductor device according to claim 26, wherein the guard pattern layer is an uppermost component of the guard ring.

28. A method of manufacturing a semiconductor device, comprising:
providing a substrate including a scribe lane region and a chip region;
forming a guard ring in the chip region;
forming a key trench in the scribe lane region; and
forming a buffer trench in the scribe lane region between the guard ring and the key trench,
wherein the buffer trench is configured to reduce mechanical stress transmission or mitigate crack propagation during wafer singulation.
